(19) United States
(12) Patent Application Publication
(10) Pub. No.: US 2025/0143022 A1
(43) Pub. Date: May 1, 2025

(54) Ultraviolet LED device and manufacturing method therefor

(71) Applicant: SUZHOU UVCANTEK CO., LTD., Suzhou (CN)

(72) Inventors: Shuang ZHANG, Suzhou (CN); Hongbo LUO, Suzhou (CN); Hongxia LI, Suzhou (CN)

(73) Assignee: SUZHOU UVCANTEK CO., LTD., Suzhou (CN)

(21) Appl. No.: 19/012,550

(22) Filed: Jan. 7, 2025

Related U.S. Application Data
(63) Continuation of application No. PCT/CN2023/138755, filed on Dec. 14, 2023.

(30) Foreign Application Priority Data
Apr. 3, 2023 (CN) 202310344473.2

(51) Int. Cl. H10H 20/821; H10H 20/01; H10H 20/812; H10H 20/815; H10H 20/816; H10H 20/825; H10H 20/841

(52) U.S. Cl. CPC H10H 20/821; H10H 20/0137; H10H 20/017; H10H 20/034; H10H 20/812; H10H 20/815; H10H 20/8162; H10H 20/825; H10H 20/841

(57) ABSTRACT

An ultraviolet LED device and a manufacturing method therefor is provided according to an embodiment of the disclosure. The ultraviolet LED device includes: a substrate (1), an AlN buffer layer (2), an n-AlGaN layer (3), a quantum well region (4), an electron blocking layer (5), a p-type GaN layer (6), and an etched trench region (7). The AlN buffer layer (2) is disposed on the substrate (1). The n-AlGaN layer (3) is disposed on the AlN buffer layer (2). The quantum well region (4) is disposed on the n-AlGaN layer (3). The electron blocking layer (5) is disposed on the quantum well region (4). The p-type GaN layer (6) is disposed on the electron blocking layer (5). The etched trench region (7) is etched downwards from the p-type GaN layer (6). The etched trench region (7) is obtained by etching from the p-type GaN layer (6) along a direction pointing toward the substrate (1). An etching angle of the etched trench region (7) is greater than 0 degree and less than or equal to 90 degrees.

### CROSS-REFERENCE TO RELATED APPLICATIONS

This application is a continuation of International Application No. PCT/CN2023/138755, filed on Dec. 14, 2023 which claims a priority to a Chinese patent application No. 202310344473.2, filed on Apr. 3, 2023. The disclosures of the above-referenced applications are hereby incorporated by reference in their entireties.

### TECHNICAL FIELD

The disclosure relates to a technical field of LED device, and in particular to an ultraviolet LED device and a manufacturing method therefor.

### BACKGROUND

(Al) GaN-based ultraviolet light-emitting diode (LED) has received continuous attention because of broad application prospects thereof in air purification, water purification, sterilization and disinfection, ultraviolet light therapy, biochemical testing, and confidential communication. Currently, a low extraction efficiency of light and a high operating voltage of the (Al) GaN-based ultraviolet light-emitting diode result in an electro-optical conversion efficiency thereof generally being less than 5%, thereby severely limiting a development for application of the (Al) GaN-based ultraviolet light-emitting diode. On the one hand, due to large difference in refractive indexes among various epitaxial layers of the ultraviolet LED device, and between various epitaxial layers of the ultraviolet LED device and an air interface, a large amount of photons emitted from a quantum well region are wasted, resulting in the low extraction efficiency of light of the ultraviolet LED device. On the other hand, a local heat accumulation will cause the operating voltage of the ultraviolet LED device to be too high.

Therefore, how to weaken a total reflection effect, improve the extraction efficiency of light, and obtain high-performance ultraviolet LED devices is a difficult problem that needs to be solved urgently.

### SUMMARY

The disclosure solves technical problems of low extraction efficiency of light and high operating voltage of ultraviolet LED devices in the related art by providing an ultraviolet LED device and a manufacturing method therefor.

The disclosure provides an ultraviolet LED device, comprising: a substrate, an AlN buffer layer, an n-AlGaN layer, a quantum well region, an electron blocking layer, a p-type GaN layer and an etched trench region. The AlN buffer layer is disposed on the substrate. The n-AlGaN layer is disposed on the AlN buffer layer. The quantum well region is disposed on the n-AlGaN layer. The electron blocking layer is disposed on the quantum well region. The p-type GaN layer is disposed on the electron blocking layer. The etched trench region is etched downward from the p-type GaN layer. The etched trench region is obtained by etching from the p-type GaN layer along a direction pointing toward the substrate. An etching angle of the etched trench region ranges from 0°-90°, which is greater than 0 degree and less than or equal to 90 degrees.

In some embodiments, the etched trench region is extended from the p-type GaN layer up to the substrate.

In some embodiments, am etching morphology of the etched trench region includes but not limited to a regular trapezoid shape, an inverted trapezoid shape, an arc shape, or a burr shape.

In some embodiments, an etching depth of the etched trench region is controlled by regulating a gas atmosphere, a power and a time of ICP; and/or, an etching angle of the etched trench region is controlled by regulating an angle of a mask material, and the gas atmosphere and the power of ICP.

In some embodiments, in a condition that the ultraviolet LED device is applied to a small-sized chip, an area of a bottom surface of the etched trench region is less than or equal to one-third of a surface area of a side of the substrate close to the AlN buffer layer, a length and width of the small-sized chip being both less than or equal to 100 μm; and/or, in a condition that the ultraviolet LED device is applied to a large-size chip, an area of a bottom surface of the etched trench region is less than or equal to half of a surface area of a side of the substrate close to the AlN buffer layer, a length and width of the large-sized chip being both greater than or equal to 10 mm.

In some embodiments, the ultraviolet LED device further includes: a reflection structure, which is disposed at a side of the ultraviolet LED device facing away from the substrate and is at least disposed at a sidewall and a bottom surface of the etched trench region.

In some embodiments, the reflection structure includes: a single-layer metal structure or a multi-layer film system structure.

The disclosure also provides a method for manufacturing an ultraviolet LED device, including: sequentially manufacturing an AlN buffer layer, an n-AlGaN layer, a quantum well region, an electron blocking layer, and a p-type GaN layer on a substrate to obtain an epitaxial wafer; using a positive photoresist as a mask, and performing an etching on the epitaxial wafer of the ultraviolet LED device up to the n-AlGaN layer by using the inductively coupled plasma; using the positive photoresist as a mask and regulating a distance between the mask and the p-type GaN layer, so that the positive photoresist has an angle relative to a mesa, and performing the etching up to the AlN buffer layer; etching a cutting track to obtain an etched trench region; using a negative photoresist as a mask and evaporating and coating an n-type electrode on the n-AlGaN layer by electron beam evaporation; using the negative photoresist as a mask and evaporating and coating a p-type electrode on the p-type GaN layer by electron beam evaporation; using a negative photoresist as a mask and evaporating and coating a reflection layer and a p-metal electrode connection layer between the n-type electrode and the p-type electrode by electron beam evaporation; and manufacturing an n-pad metal layer and a p-pad metal layer.

In some embodiments, after the epitaxial wafer is obtained, the manufacturing method further comprises: using a cleaning fluid to ultrasonically clean the epitaxial wafer to remove an organic matter on a surface of the epitaxial wafer;

rinsing the epitaxial wafer with a deionized water and then spin-drying the epitaxial wafer.

In some embodiments, the method for manufacturing the ultraviolet LED device further includes: evaporating and coating a first passivation layer on the p-type GaN layer by using PECVD, wherein the first passivation layer is used to protect an n-region of the n-type electrode which needs to be connected to the p-type electrode and a p-region of the p-type electrode, and corrode a second passivation layer of the p-region and the n-region, a material of the second passivation layer comprising a silicon dioxide.

### BRIEF DESCRIPTION OF DRAWINGS

FIG. 1 is a cross-sectional view of an ultraviolet LED device according to an embodiment of the disclosure;

FIG. 2 is a cross-sectional view of another ultraviolet LED device according to an embodiment of the disclosure;

FIG. 3 is a schematic flow chart of a method for manufacturing an ultraviolet LED device according to an embodiment of the disclosure; and

FIG. 4 is a cross-sectional view of yet another ultraviolet LED device according to an embodiment of the disclosure.

In the accompanying drawings, corresponding relationships between reference signs and component names are as follows: 1, substrate; 2, AlN buffer layer; 3, n-AlGaN layer; 4, quantum well region; 5, electron blocking layer; 6, p-type GaN layer; 7, etched trench region; 8, n-type electrode; 9, p-type electrode; 10, first passivation layer; 11, reflection layer; 12, p-metal electrode connection layer; 13, second passivation layer; 14, p-pad metal layer; 15, n-pad metal layer.

### DESCRIPTION OF EMBODIMENTS

The disclosure solves technical problems of low extraction efficiency of light and high operating voltage of ultraviolet LED devices in the related art by providing an ultraviolet LED device and a method for manufacturing the ultraviolet LED device.

Technical solutions provided according to an embodiment of the disclosure for solving the above technical problems have an overall idea as follows.

Designs of etching for a light-emitting region include three parts including an etching depth, an etching angle and a size of etching region. 1) As for the etching depth and the etching angle, a maximum etching depth may be a sum of an overall thickness of epitaxial layers, and the etching angle may be greater than 0 degrees and less than or equal to 90 degrees. In the disclosure, the etching depth and the etching angle can be regulated and controlled by controlling parameters of mask processes including but not limited to parameters of photoresist, silicon dioxide and the like and by controlling parameters of ICP (Inductively Coupled Plasma) etching process. The etching depth may be regulated by regulating a gas atmosphere, a power and a time of ICP. The etching angle may be regulated by regulating an angle of a mask material, and the gas atmosphere and the power of ICP. 2) As for the size of etching region: the etching for the light-emitting region may increase a reflection region while reducing a contact area of a p-type electrode. Therefore, under a premise of ensuring an electrical performance, the number of etchings for the light-emitting region is increased as much as possible, so as to increase the reflection area.

In some embodiments, an area and angle of an etched trench region can be designed according to sizes of different chips. For example, for a small-sized chip with a length and width less than or equal to 100 μm, an area of a bottom surface of the etched trench region 7 is less than or equal to one-third of a surface area of a side of the substrate close to the AlN buffer layer, and the etching angle is between 45° and 60°. For a large-sized chip with a length and width greater than or equal to 10 mm, an area of a bottom surface of the etched trench region 7 is less than or equal to half of a surface area of a side of the substrate close to the AlN buffer layer, and the etching angle may be appropriately reduced in comparison to that of the small-sized chip.

In some embodiments, the ultraviolet LED device further includes: a reflection structure, which is disposed at a side of the ultraviolet LED device facing away from the substrate and is at least disposed at a sidewall and a bottom surface of the etched trench region.

The reflection structure has an reflection action on photons emitted by the quantum well region, thereby reducing a wastage such as an absorption and a total reflection of the photons in the ultraviolet LED device. Moreover, since the etched trench region has a single type of film layer and the photons are prone to escape to be absorbed and wasted, the sidewall and bottom surface of the etched trench region should be covered with the above reflection structure.

It should be noted that, in a condition that the reflection structure completely covers the side of the ultraviolet LED device facing away from the substrate, the photons escaping from the etched trench region can be reflected back, thereby greatly reducing the escaping of photons.

In some embodiments, the reflection structure may include a single-layer metal structure in which a metal may be Al, Rh, Ag, Ni and the like, or may also include a stacked-layer metal structure in which a metal may be a combination of two or more of Al, Rh, Ag, Ni, Au, Ti, Pt, Cr, Cu, Pd, and ITO, or may include a multi-layer film system structure such as ODR (Omnidirectional Reflector) and DBR (Distributed Bragg Reflector).

It should be noted that a use of the single-layer metal structure can reduce a thickness of the ultraviolet LED device, thereby reducing a volume of a chip. A use of the stacked-layer metal structure can increase a service life of a chip. A use of the multi-layer film system structure can obtain a better reflection effect on escaping photons.

It should be noted that the reflection structure used in the disclosure can serve as a sidewall of a mesa and a reflection layer for etching out the light-emitting region. The reflection structure, when adopting the single-layer metal structure and the stacked-layer metal structure, may also play a role for a connection of an n-type electrode and a p-type electrode, and a role in an expansion for current respectively, thereby increasing a performance of the ultraviolet LED device while reducing steps and costs of preparation process for the ultraviolet LED device.

In some embodiments of the disclosure, a wavelength of an ultraviolet light emitted by the ultraviolet LED device may ranges from 100 nm-400 nm.

In order to better understand the above technical solutions, the above technical solutions will be described in detail below in conjunction with the accompanying drawings and embodiments.

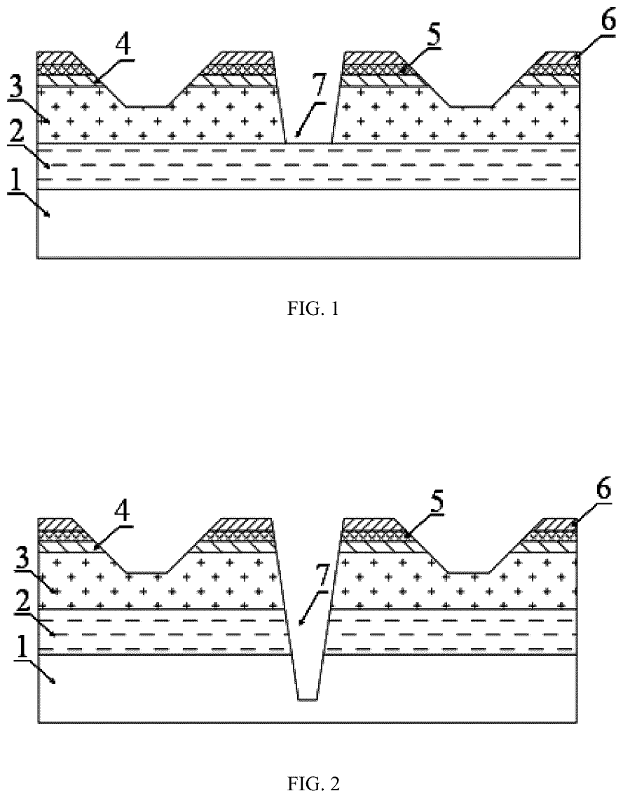

FIG. 1 is a cross-sectional view of an ultraviolet LED device according to an embodiment of the disclosure. FIG. 2 is a cross-sectional view of another ultraviolet LED device according to an embodiment of the disclosure. Referring to FIG. 1 and FIG. 2, an ultraviolet LED device according to an embodiment of the disclosure includes: a substrate 1, an AlN buffer layer 2, an n-AlGaN layer 3, a quantum well region 4, an electron blocking layer 5, a p-type GaN layer 6 and an etched trench region 7. The AlN buffer layer 2 is on the substrate 1. The n-AlGaN layer 3 is on the AlN buffer layer 2. The quantum well region 4 is on the n-AlGaN layer 3. The electron blocking layer 5 is on the quantum well region 4. The p-type GaN layer 6 is on the electron blocking layer 5. An etched trench region 7 is etched out downward from the p-type GaN layer 6. An etching depth kₑ of the etched trench region 7 may be less than or equal to 500 μm, and an etching angle of the etched trench region 7 is greater than 0° and less than or equal to 90°.

It is easy to understand that the p-type GaN layer 6 may also be made of AlGaN as a material for film layer, which does not affect the technical solution and technical effect of the embodiments of the disclosure.

In some embodiments, the etched trench region 7 is etched out from the p-type GaN layer 6 up to the substrate 1. An etching morphology of the etched trench region 7 includes an inverted trapezoid shape, an arc shape, and a burr shape. An etching depth of the etched trench region 7 is controlled by regulating a gas atmosphere, a power and a time of ICP. An etching angle of the etched trench region 7 is controlled by regulating an angle of the mask material, and the gas atmosphere and the power of ICP.

In some embodiments, a substrate 1 is a sapphire substrate.

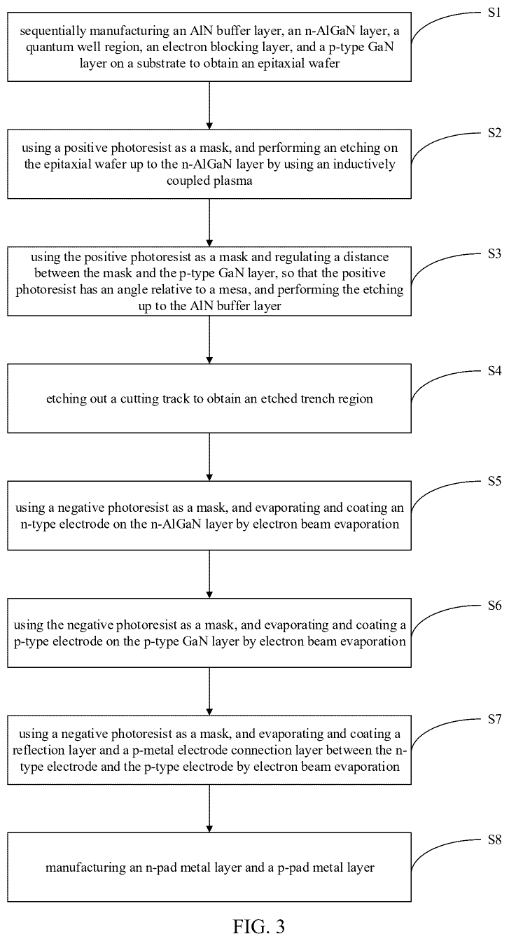

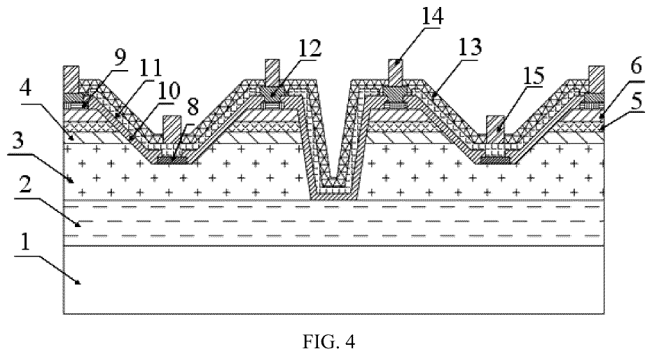

FIG. 3 is a schematic flow chart of a method for manufacturing an ultraviolet LED device according to an embodiment of the disclosure; and FIG. 4 is a cross-sectional view of yet another ultraviolet LED device according to an embodiment of the disclosure. Referring to FIG. 3 and FIG. 4, the method for manufacturing an ultraviolet LED device according to an embodiment of the disclosure includes steps S1 to S8.

In step S1, an AlN buffer layer 2, an n-AlGaN layer 3, a quantum well region 4, an electron blocking layer 5, and a p-type GaN layer 6 are sequentially manufactured on a substrate 1 to obtain an epitaxial wafer.

In order to clean a surface of the epitaxial wafer to improve a yield and performance of the ultraviolet LED device, the following are also included after the epitaxial wafer is obtained:

the epitaxial wafer is ultrasonically cleaned for 5 minutes using a cleaning solution to remove an organic matter on the surface of the epitaxial wafer, then rinsed with a deionized water for 5 minutes and dried with a spin dryer.

In some embodiments, the cleaning solution is acetone and isopropyl alcohol.

In step S2, a positive photoresist is used as a mask, and an etching is performed on the epitaxial wafer for the ultraviolet LED device up to the n-AlGaN layer 3 in the epitaxial wafer by using the inductively coupled plasma.

In some embodiments, during a process of performing the etching up to the n-AlGaN layer 3 by using the inductively coupled plasma, a ratio of a thickness of the mask to an etching depth for etching up to the n-AlGaN layer is 3:1, and the etching depth ranges from 670 to 850 nm.

In order to further improve the yield and performance of the ultraviolet LED device, an etched epitaxial wafer is placed in a degumming solution of 85° C., the acetone and isopropanol for ultrasonic treatments for 10 min, 5 min and 5 min, respectively, and then rinsed with the deionized water for 5 min to remove the positive photoresist on the surface of the etched epitaxial wafer.

In step S3, the positive photoresist with a thickness of 5-6 μm is used as a mask, and a distance between the mask and the p-type GaN layer 6 is regulated, so that the positive photoresist has an angle relative to a mesa, and the etching is performed up to the AlN buffer layer 2.

In some embodiments, the etching being performed up to the AlN buffer layer 2 includes:

etching the mesa by using a plasma in a mixed atmosphere of BCl₃ and Cl₂, with an etching depth of 2.5 μm and an etching angle of 54°.

In step S4, a cutting track is etched out to obtain an etched trench region 7.

In some embodiments, an etching depth is 2 μm.

In step S5, a negative photoresist is used as a mask, and an n-type electrode 8 is evaporated and coated on the n-AlGaN layer 3 by electron beam evaporation.

In some embodiments, after the n-type electrode 8 is evaporated and coated, the manufacturing method according to an embodiment of the disclosure further includes:

removing photoresists on the n-type electrode 8, and then performing an annealing on the n-type electrode 8 in a rapid annealing furnace under a nitrogen atmosphere and at 850° C. for 45 seconds, to form an ohmic contact at an interface between the n-type electrode 8 and the n-AlGaN layer 3.

In some embodiments, a material for evaporating and coating is Cr, Al, Ti, Ni or Au.

In step S6, the negative photoresist is used as a mask, and a p-type electrode 9 is evaporated and coated on the p-type GaN layer 6 by electron beam evaporation.

In some embodiments, after the p-type electrode 9 is evaporated and coated, the manufacturing method according to an embodiment of the disclosure further includes:

removing photoresists on the p-type electrode 9, and then performing an annealing on the p-type electrode 9 in a rapid annealing furnace under an oxygen atmosphere and at 500° C. for 5 minutes to form an ohmic contact at an interface between the p-type electrode 9 and the p-GaN layer 6.

In some embodiments, the p-type electrode 9 has a structure including but not limited to NiAu, ITO or Rh, and a thickness thereof ranges from 10 to 70 nm.

In order to prevent the n-type electrode 8 and the p-type electrode 9 from being connected and thus causing a short circuit of chip, before the p-type electrode 9 is evaporated and coated on the p-type GaN layer 6 by electron beam evaporation, the manufacturing method according to an embodiment of the disclosure further includes:

evaporating and coating a first passivation layer on the p-type GaN layer by using PECVD (Plasma Enhanced Chemical Vapor Deposition). The first passivation layer is used to protect an n-region of the n-type electrode that needs to be connected to the p-type electrode and a p-region of the p-type electrode, and corrode a second passivation layer of the p-region and the n-region. A material of the second passivation layer includes a silicon dioxide. A metal for evaporating and coating may be Cr, Al, Ti, Pt or Au. A total thickness of the first passivation layer is 300 nm. The first passivation layer, while connecting and thickening the n-type electrode 8, also plays a role in enhancing a transmittance of film layers in a film system of ODR and also plays a role in passivation.

In step S7, a negative photoresist is used as a mask, and a reflection layer 11 and a p-metal electrode connection layer 12 are evaporated and coated between the n-type electrode 8 and the p-type electrode 9 by electron beam evaporation. A Cr/Al-based reflection structure is evaporated and coated by electron beam evaporation, for not only playing a role of reflection, but also thickening an n-type metal electrode to make the n-type metal electrode to have more uniform expansion for current, where a thickness of a metal Al is greater than 120 nm, and a stripping liquid is used for stripping.

In step S8, an n-pad metal layer 15 and a p-pad metal layer 14 are manufactured.

In this step, the negative photoresist is used as a mask, and metal electrodes are evaporated and coated on a portion of the reflection layer 11 and the p-metal electrode connection layer 12 by electron beam evaporation, and the negative photoresist is stripped off by using the stripping liquid to obtain the n-pad metal layer 15 and the p-pad metal layer 14.

In some embodiments, an evaporated and coated metal electrode is an AuSn electrode with a total thickness of 1.9 μm.

In order to prevent the reflection layer 11 and the p-metal electrode connection layer 12 from being connected and thus causing a short circuit of chip, before the n-pad metal layer 15 and the p-pad metal layer 14 are manufactured, the manufacturing method according to an embodiment of the disclosure further includes:

evaporating and coating a second passivation layer 13 with a thickness of 1 μm on a portion of the first passivation layer 10, the reflection layer 11 and the p-metal electrode connection layer 12 by using PECVD, and etching a silicon dioxide above the portion of the reflection layer 11 and the p-metal electrode connection layer 12 to ensure that the n-pad metal layer 15 is conductive with the reflection layer 11, and the p-pad metal layer 14 is conductive with the p-metal electrode connection layer 12.

The LED device manufactured according to the embodiment of the disclosure can emit a wavelength of an ultraviolet light in a range of UVC wave band. In some embodiments the LED device has an adopted etching depth of 2.5 μm, has an adopted etching angle of 54°, and is an LED device which has a pixel array with a reflection structure.

An LED device is provided according to an embodiment of the disclosure based on etching for the light-emitting region. The LED device can reduce a total reflection effect of the photons among various epitaxial layers of the ultraviolet LED device, and between various epitaxial layers of the ultraviolet LED device and an air interface. The reflection structure is disposed at the etched trench region, to improve an extraction efficiency of light of the ultraviolet LED, while reducing local heat accumulation, lowering an operating voltage of the ultraviolet LED device and extending service life of the ultraviolet LED device.

One or more embodiments provided in the disclosure have at least the following technical effects or advantages. The etched trench region is etched out at the light-emitting region, to reduce the total reflection effect and local heat accumulation of photons at the epitaxial layers. The reflection structure is disposed at the sidewall and bottom of the etched trench region to reflect the photons to a back of the substrate as much as possible, thereby improving an extraction efficiency of light of the chip, reducing the operating voltage of the ultraviolet LED device, and extending service life of the ultraviolet LED device.

Although some embodiments of the disclosure have been described, additional changes and modifications may be made to these embodiments once those skilled in the art understand the basic creative concepts. Therefore, it is intended that the appended claims be interpreted as including the embodiment as well as all changes and modifications that fall within the scope sought for by the disclosure.

Obviously, those skilled in the art can make various changes and modifications to the disclosure without departing from the spirit and scope of the disclosure. Thus, if these modifications and variations of the disclosure fall within the scope of the claims of the disclosure and the equivalent technologies thereof, the disclosure is also intended to include these modifications and variations.

What is claimed is:

1. An ultraviolet LED device, comprising a substrate, an AlN buffer layer, an n-AlGaN layer, a quantum well region, an electron blocking layer, a p-type GaN layer and an etched trench region, wherein,
the AlN buffer layer is disposed on the substrate;
the n-AlGaN layer is disposed on the AlN buffer layer;
the quantum well region is disposed on the n-AlGaN layer;
the electron blocking layer is disposed on the quantum well region;
the p-type GaN layer is disposed on the electron blocking layer; and
the etched trench region is etched out from the p-type GaN layer along a direction pointing toward the substrate, an etching angle of the etched trench region being greater than 0 degree and less than or equal to 90 degrees.

2. The ultraviolet LED device of claim 1, wherein the etched trench region is extended from the p-type GaN layer to the substrate.

3. The ultraviolet LED device of claim 1, wherein an etching morphology of the etched trench region comprises an inverted trapezoid shape, an arc shape, and a burr shape.

4. The ultraviolet LED device of claim 1, wherein an etching depth of the etched trench region is controlled by regulating a gas atmosphere, a power and a time of ICP; and/or,
an etching angle of the etched trench region is controlled by regulating an angle of a mask material, and a gas atmosphere and a power of ICP.

5. The ultraviolet LED device of claim 1, wherein in a condition that the ultraviolet LED device is applied to a small-sized chip, an area of a bottom surface of the etched trench region is less than or equal to one-third of a surface area of a side of the substrate close to the AlN buffer layer, a length and width of the small-sized chip being both less than or equal to 100 μm; and/or,
in a condition that the ultraviolet LED device is applied to a large-size chip, an area of a bottom surface of the etched trench region is less than or equal to half of a surface area of a side of the substrate close to the AlN buffer layer, a length and width of the large-sized chip being both greater than or equal to 10 mm.

6. The ultraviolet LED device of claim 1, further comprising: a reflection structure, which is disposed at a side of the ultraviolet LED device facing away from the substrate and is at least disposed at a sidewall and a bottom surface of the etched trench region.

7. The ultraviolet LED device of claim 6, wherein the reflection structure comprises: a single-layer metal structure or a multi-layer film system structure.

8. A method for manufacturing an ultraviolet LED device, comprising:
sequentially manufacturing an AlN buffer layer, an n-AlGaN layer, a quantum well region, an electron blocking layer, and a p-type GaN layer on a substrate to obtain an epitaxial wafer;
using a positive photoresist as a mask, and performing an etching on the epitaxial wafer up to the n-AlGaN layer by using an inductively coupled plasma;
using the positive photoresist as a mask and regulating a distance between the mask and the p-type GaN layer, so that the positive photoresist has an angle relative to a mesa, and performing the etching up to the AlN buffer layer;
etching out a cutting track to obtain an etched trench region;
using a negative photoresist as a mask, and evaporating and coating an n-type electrode on the n-AlGaN layer by electron beam evaporation;
using the negative photoresist as a mask, and evaporating and coating a p-type electrode on the p-type GaN layer by electron beam evaporation;
using a negative photoresist as a mask, and evaporating and coating a reflection layer and a p-metal electrode connection layer between the n-type electrode and the p-type electrode by electron beam evaporation; and
manufacturing an n-pad metal layer and a p-pad metal layer.

9. The method for manufacturing the ultraviolet LED device of claim 8, after the epitaxial wafer is obtained, further comprising:
ultrasonically cleaning the epitaxial wafer with a cleaning solution to remove an organic matter on a surface of the epitaxial wafer; and
rinsing the epitaxial wafer with a deionized water and then spin-drying the epitaxial wafer.

10. The method for manufacturing the ultraviolet LED device of claim 8, before the evaporating and coating the p-type electrode on the p-type GaN layer by electron beam evaporation, further comprising:
evaporating and coating a first passivation layer on the p-type GaN layer by using PECVD, wherein the first passivation layer is used to protect an n-region of the n-type electrode which is connected to the p-type electrode and a p-region of the p-type electrode, and corrode a second passivation layer of the p-region and the n-region, a material of the second passivation layer comprising a silicon dioxide.
